(19) United States
(12) Patent Application Publication
(10) Pub. No.: US 2008/0076257 A1
(43) Pub. Date: Mar. 27, 2008

(54) Method for manufacturing semiconductor device

(75) Inventor: Mitsunari Sukekawa, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/898,982

(22) Filed: Sep. 18, 2007

(30) Foreign Application Priority Data
Sep. 27, 2006 (JP) 2006-261817

(51) Int. Cl. H01L 21/311

(52) U.S. Cl. 438/702; 257/E21.254

(57) ABSTRACT

The present invention provides a method for manufacturing a semiconductor device which can perform good processing of line edge roughness, comprising steps of: forming a processed film on a substrate; forming a bottom layer comprising an organic film on the processed film; forming a top layer comprising a silicon component on the bottom layer; patterning the top layer; selectively removing a residue on a surface of the bottom layer without etching the bottom layer after the top layer patterning step; etching the bottom layer with the top layer as a mask; and etching the processed film with the bottom layer as a mask after the bottom layer etching step.

This application is based upon and claims the benefit of priority from Japanese patent application No. 2006-261817, filed on Sep. 27, 2006, the disclosure of which is incorporated herein in its entirety by reference.

### BACKGROUND OF THE INVENTION

1. Field of the Invention

The present invention relates to a method for manufacturing a semiconductor device.

2. Related Art

In conjunction with development of semiconductor microfabrication technology in recent years, an ArF resist which is patterned by short-wavelength light is used. As for an ArF lithographic technique, it is known that it uses a two-layer resist as a mask for dry etching, of which an upper layer (hereinafter referred as “top layer”) is a photosensitive resist containing silicon and a lower layer (hereinafter referred as “bottom layer”) is an organic film. Such a technique is effective at forming a fine pattern since the bottom layer becomes an antireflection coating and prevents the top layer from being exposed to reflected light from underneath layers.

A conventional patterning technique will be described with reference to FIGS. 1A to 1D. First, substrate 14 is laminated with a film to be processed (e.g., insulating film 13), bottom layer 12 and top layer 11 in this order. Subsequently, top layer 11 is patterned by using the lithographic technique as shown in FIG. 1A. Second, bottom layer 12 is etched with top layer 11 thus patterned as a mask as shown in FIG. 1B. Subsequently, insulating film 13 is etched with bottom layer 12 and top layer 11 as masks as shown in FIG. 1C. Finally, the patterning for insulating film 13 is completed by removing bottom layer 12 as shown in FIG. 1D.

In such a patterning technique, there are the cases where a substance which is presumably residue 15 derived from top layer 11 remains on bottom layer 12 exposed after patterning top layer 11 as shown in FIG. 2A. If bottom layer 12 is etched as-is, there is a possibility that residue 15 may become a mask and etching residue of bottom layer 12 may be generated. Such a residue 15 often remained at ends of a resist pattern, and so the shape of the pattern ends sometimes did not become sharp. To be more specific, the residue sometimes deteriorated line edge roughness.

In the case where residue 15 remains before etching insulating film 13 as shown in FIG. 2B, accuracy of insulating film processing may further deteriorate since the etching of insulating film 13 is blocked. Furthermore, if the residue 15 still remains after insulating film etching, it blocks removal of top layer 11 and bottom layer 12 and may be a cause of a removal residue.

Therefore, expectations are placed on a technique of preventing the residue of top layer 11 from becoming a cause of deterioration of the line edge roughness and the removal residue.

In conjunction with the above, Japanese Patent Laid-Open No. 09-232218 discloses that the top layer is removed by ashing with a gas containing fluorine atoms and carbon atoms. It is described that removing performance improves in the case of using this technique.

Japanese Patent Laid-Open No. 06-020942 discloses that the bottom layer is etched with a gas containing oxygen gas and a fluorine compound gas and only the oxygen gas is used thereafter.

Japanese Patent No. 2754677 discloses that the bottom layer is patterned by the dry etching which uses oxygen gas in which a fluorine compound gas is added thereto.

Even in the cases of using those techniques, however, it has been difficult to strike a balance between high-precision patterning and good removing performance.

### SUMMARY OF THE INVENTION

An object of the present invention is to provide a method for manufacturing a semiconductor device which can perform good processing of line edge roughness.

Another object of the present invention is to provide a method for manufacturing a semiconductor device which can perform good processing of the line edge roughness after preventing a removal residue of a resist layer.

Means for attaining the objects are expressed as follows. In the following expression, symbols indicated in the drawings are described in parentheses as reference. However, the present invention is not limited thereto.

The present invention provides a method for manufacturing a semiconductor device, comprising:

(step S10-1) forming a processed film (3) on a substrate (4);

(step S10-2) forming a bottom layer (2) comprising an organic film on the processed film (3);

(step S10-3) forming a top layer (1) comprising silicon on the bottom layer (2);

(step S20) patterning the top layer (1);

(step S30) removing a residue on a surface of the bottom layer (2) after the top layer patterning (step S20);

(step S40) etching the bottom layer (2) with a patterned top layer (1) as a mask; and

(step S60) etching the processed film (3) with the bottom layer (2) as a mask after the bottom layer etching (S40).

Thus, the residue removing step (S30) is provided so that, even if the residue of the top layer is generated in the top layer patterning step (S20), the residue is removed. Therefore, no adverse effect of the residue arises in the steps from the bottom layer etching step (S40) onward.

According to the above method, it is desirable to remove the residue by performing dry etching with a gas containing halogen as an etching gas in the residue removing step (S30).

The top layer (1) contains silicon. A main component of the residue is presumably the silicon. As described above, the gas containing halogen is used as the etching gas so that the silicon is efficiently removed and the residue can be more securely removed.

According to the above method, it is desirable that the gas containing halogen be a gas containing CF₄.

According to the above method, it is desirable that the top layer (1) be a photosensitive resist. It is also desirable that the top layer patterning step (S20) be performed by an ArF lithographic technique.

According to the above method, it is desirable that the bottom layer etching step (S40) includes a step of performing the dry etching by using a gas containing hydrogen.

Thus, if the bottom layer (2) is dry-etched by using the gas containing hydrogen, side etch is curbed. As the side etch is curbed, a stroke width on processing the processed film is easily securable.

According to the above method, it is desirable that the bottom layer etching step (S40) includes a first bottom layer etching step (step S40-1) of performing the dry etching with a gas containing oxygen as the etching gas and a second bottom layer etching step (step S40-2) of performing the dry etching with a mixed gas containing hydrogen and nitrogen as the etching gas after the first bottom layer etching (step S40-1).

Thus, the etching is performed by using the gas containing oxygen so that the silicon contained in the top layer is oxidized. Therefore, etching tolerance of the top layer (1) can be improved. The bottom layer (2) can be etched in a desired pattern by improving the etching tolerance of the top layer (1) which is a mask material.

As for the above method, it is desirable that the etching gas used for the dry etching in the bottom layer etching step (S40) contains no halogen.

When performing the etching with the gas containing hydrogen, a product generated by reaction between halogen and hydrogen is curbed if no halogen atoms are included. Therefore, generation of dust inside an etching chamber can be curbed.

As for the above method, it is desirable to include a top layer exfoliating step (S50) of removing the top layer (1) by the dry etching after the bottom layer etching step (S40). And it is desirable to use the gas containing halogen as the etching gas for top layer removal in the top layer removing step (S50).

Thus, when removing the top layer, it is possible to securely remove the top layer by using the gas containing halogen.

As for the above method, it is desirable that the etching gas for removing the top layer contains CF₄.

As for the above method, it is desirable that the processed film (3) be a silicon dioxide film.

As for the above method, it is desirable that the bottom layer (2) be a novolac-acrylic resin material.

The present invention provides the method for manufacturing a semiconductor device, which can perform processing of the processed film of small line edge roughness.

The present invention further provides the method for manufacturing a semiconductor device, which can perform processing of the processed film of small line edge roughness after preventing a removal residue of a resist layer.

### BRIEF DESCRIPTION OF THE DRAWINGS

FIGS. 1A to 1D are sectional views of a manufacturing process for a conventional method;

FIGS. 2A and 2B are sectional views for explanating the problems of the conventional method;

FIG. 3 is a flowchart of a method for manufacturing a semiconductor device according to the present invention; and

FIGS. 4A to 4G are sectional views of the manufacturing process according to the present invention.

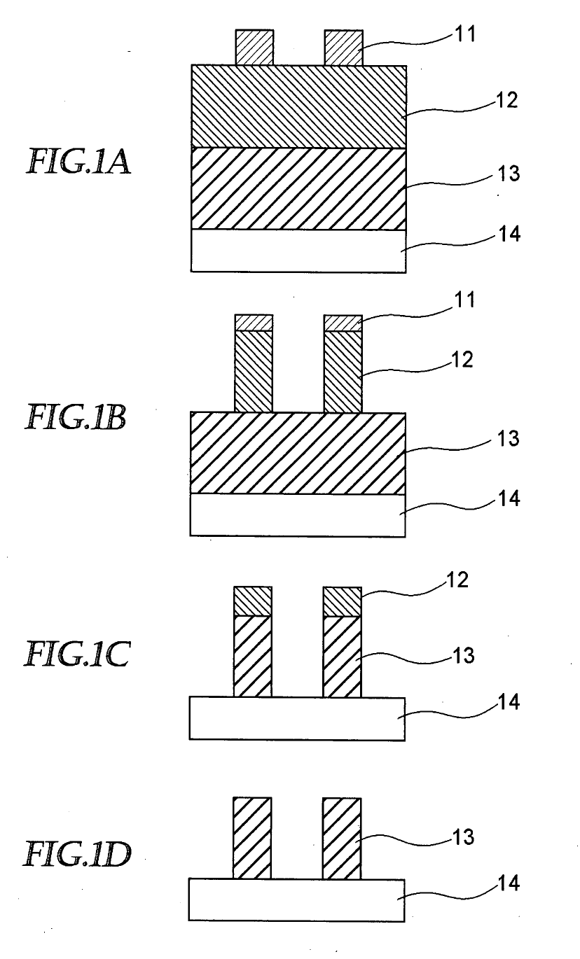

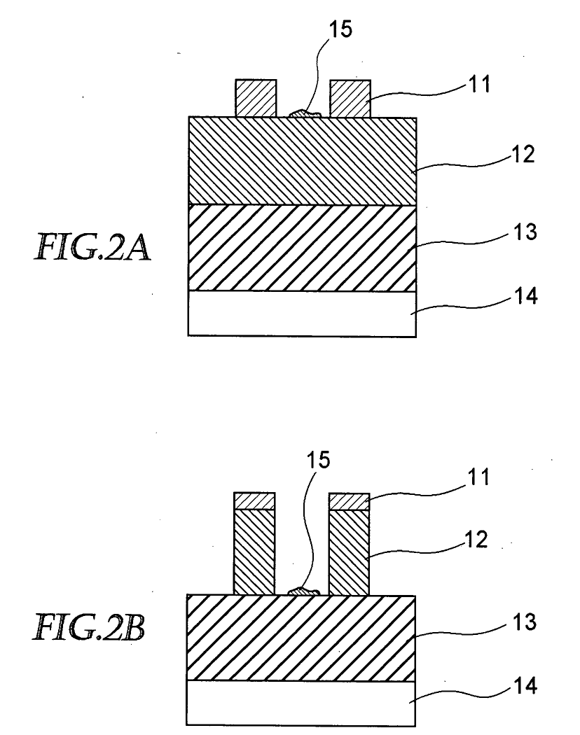

### DETAILED DESCRIPTION OF THE PREFERRED EMBODIMENTS

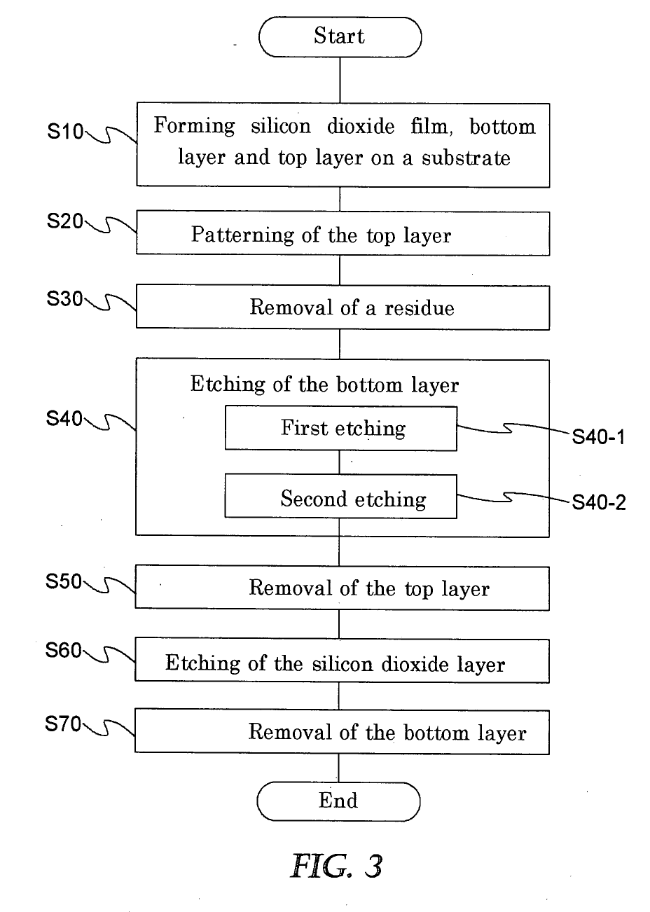

Embodiments of the present invention will be described with reference to the drawings. FIG. 3 is a flowchart of a method for manufacturing a semiconductor device according to this embodiment. The method for manufacturing a semiconductor device forms a processed film patterned on a substrate by processing of steps S10 to S70 shown in FIG. 3. Details of each step of the processing will be described below. This embodiment will be described by taking as an example a process of patterning a silicon dioxide film on a storage device such as a DRAM (Dynamic Random Access Memory). In the field of the storage device such as the DRAM, a higher-density pattern and a sharply formable pattern are demanded, which are suitable as applications of the present invention.

### Steps S10-1 to 10-3: Lamination of Materials

First, a processed film is formed on a substrate 4 (step S10-1). The substrate 4 is a metallic material for instance. The processed film is insulating film (silicon dioxide film) 3 for instance. The following will describe the case where the processed film is insulating film 3. Insulating film 3 can be formed by a CVD method. Subsequently, bottom layer 2 is formed on insulating film 3 (step S10-2). Bottom layer 2 is an organic film. A novolac-acrylic resin antireflection coating can be cited as the organic film. Bottom layer 2 can be formed by a spin coating method. Top layer 1 is further formed on bottom layer 2. Top layer 1 is a photosensitive resist containing a silicon component. The photosensitive resist is a siloxane photosensitive ArF resist of which silicon content is 19.5% for instance.

### Step S20: Patterning of Top Layer

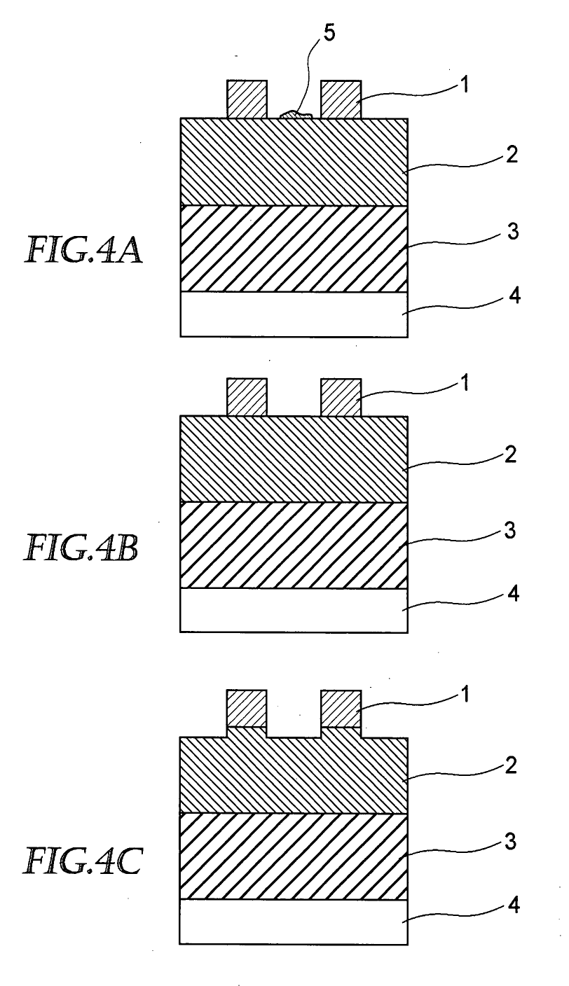

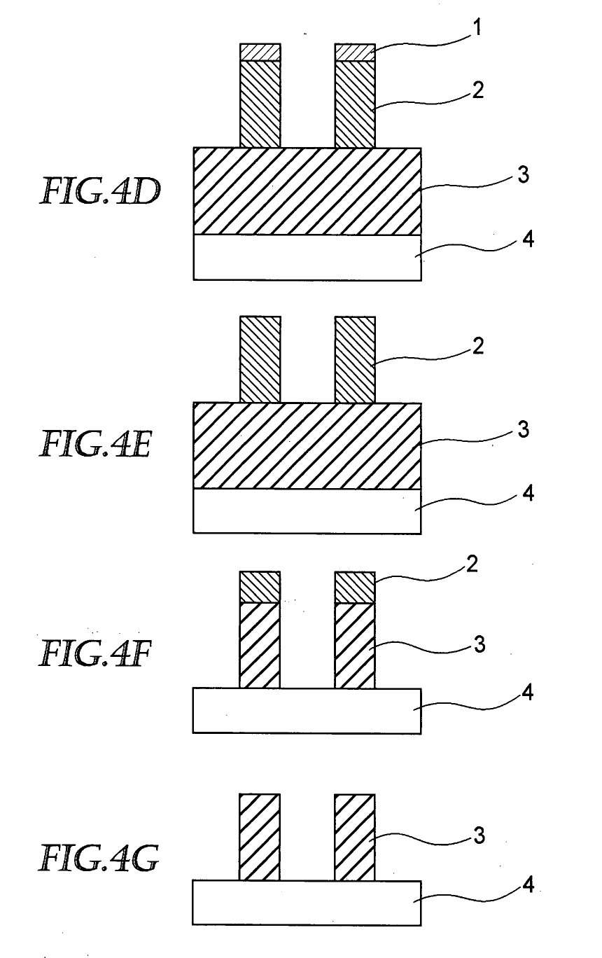

As shown in FIG. 4A, top layer 1 is subsequently patterned by using a lithographic technique. In this case, there is a possibility that residue 5 of top layer 1 may remain on a surface of a portion in which bottom layer 2 is exposed after top layer 1 is removed. Residue 5 is presumably a residue derived from top layer 1 including the silicon component.

### Step S30: Removal of Residue

As shown in FIG. 4B, residue 5 is subsequently removed. The removal of residue 5 is performed by using a dry etching technique. An etching gas containing halogen atoms is used. As for such an etching gas, CF₄ can be cited for instance. As for a dry etching device, an RIE dry etching device of which RF frequency is 13.56 MHz may be used. As for etching conditions, the conditions can be cited, such as a chamber pressure of 100 mTorr, RF power of 400 W and a stage temperature of 60° C. If dry etching is performed on such conditions, only the residue can be selectively removed while hardly etching bottom layer 2. The dry etching conditions for selectively removing only the residue without etching bottom layer 2 are not limited to the above. Other conditions are allowed if the conditions such as the chamber pressure, RF power and stage temperature are adjusted.

### Step S40-1: First Bottom Layer Etching

As shown in FIG. 4C, bottom layer 2 is etched halfway with top layer 1 as a mask. This etching is the dry etching using a gas containing an oxygen gas as the etching gas. As for the gas containing oxygen, a mixed gas of nitrogen and oxygen can be cited. Thus, if the etching is performed by using the gas containing the oxygen gas, the silicon contained in top layer 1 which is the mask is oxidized and etching tolerance of top layer 1 is improved.

### Step S40-2: Second Bottom Layer Etching

As shown in FIG. 4D, bottom layer 2 is subsequently etched to the surface of insulating film 3. This etching is the dry etching using a mixed gas containing hydrogen and nitrogen as the etching gas. A flow ratio between hydrogen and nitrogen is 3:1 for instance. An oxygen radical and a hydrogen radical can be cited as those which can etch a carbon component included in bottom layer 2. Here, the oxygen radical is apt to be chemically bonded to the carbon component so that it reacts to bottom layer 2 with relatively low energy and lateral etching is apt to progress. In comparison, the hydrogen radical cannot etch the carbon component without assist of ion energy so that the etching selectively progresses in a vertical direction. To be more specific, as described above, side etch of bottom layer 2 is curbed by using a gas containing hydrogen as the etching gas. This is advantageous when securing stroke width on patterning. It is desirable that the etching gas contain no halogen atoms on the etching of second bottom layer. If the halogen atoms and hydrogen atoms are mixed, they may react to generate a product. Such a product becomes dust inside an etching chamber, which is not desirable. It is possible to prevent generation of such a reaction product by causing the etching gas to contain no halogen atoms.

### Step S50: Removal of Top Layer

As shown in FIG. 4E, top layer 1 remaining as the mask is removed next. Removal of top layer 1 is performed by the dry etching using the gas containing halogen. A CF₄ gas is exemplified as the gas containing halogen. Thus, it is possible, by using the gas containing halogen, to securely remove top layer 1 and to curb generation of a removal residue of top layer 1.

### Step S60: Etching of Insulating Film

As shown in FIG. 4F, insulating film 3 is dry-etched with bottom layer 2 as the mask next. As for the gas used for the dry etching, a C₄F₈ gas can be cited for instance.

### Step S70: Removal of Bottom Layer

As shown in FIG. 4G, bottom layer 3 remaining as the mask is subsequently removed by the dry etching. An oxygen gas is exemplified as the etching gas in this case.

The insulating film formed on the substrate is patterned in the steps S10 to S70 described above. This embodiment can exert the following effects.

First, even if the residue exists after a top layer patterning step, the residue can be securely removed since a residue removing step is provided. The residue is apt to be generated at an end of a pattern, and may deteriorate line edge roughness. Therefore, the line edge roughness can be improved by removing the residue.

Furthermore, it becomes possible to curb the side etch by using a gas system containing hydrogen as the gas for the bottom layer etching. In this case, it is possible, by using no halogen gas, to curb generation of a product generated by reaction between the halogen gas and the hydrogen and also curb generation of the dust inside the etching chamber.

Moreover, after the bottom layer etching step, the top layer is removed by using a halogen-containing gas so that the top layer which is a mask material can be securely removed. Thus, no residue of the top layer remains in the processing thereafter so as to further improve the line edge roughness.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A method for manufacturing a semiconductor device, comprising the steps of:
forming a processed film on a substrate;
forming a bottom layer comprising an organic film on the processed film;
forming a top layer comprising a silicon component on the bottom layer;
patterning the top layer;
selectively removing a residue on a surface of the bottom layer after the top layer patterning;
etching the bottom layer with a patterned top layer as a mask after the residue removing; and
etching the processed film with the bottom layer as a mask after the bottom layer etching.

2. The method for manufacturing a semiconductor device according to claim 1, wherein the residue is removed by performing dry etching with a gas containing halogen as an etching gas in the residue removing step.

3. The method for manufacturing a semiconductor device according to claim 2, wherein the gas containing halogen is a gas containing CF₄.

4. The method for manufacturing a semiconductor device according to claim 1, wherein the top layer is a photosensitive resist and the top layer patterning is performed by an ArF lithographic technique.

5. The method for manufacturing a semiconductor device according to claim 1, wherein the bottom layer etching step includes performing the dry etching by using a gas containing hydrogen.

6. The method for manufacturing a semiconductor device according to claim 5, wherein the gas containing hydrogen contains no halogen atoms.

7. The method for manufacturing a semiconductor device according to claim 5, wherein:
the step of etching the bottom layer includes:
a first bottom layer etching for performing the dry etching with a gas containing oxygen as an etching gas; and
a second bottom layer etching for performing the dry etching with a mixed gas containing hydrogen and nitrogen as the etching gas after the first bottom layer etching.

8. The method for manufacturing a semiconductor device according to claim 1,
wherein the method further comprises the step of removing the top layer by dry etching after the bottom layer etching, and
wherein a gas containing halogen is used as an etching gas for top layer exfoliation in the top layer exfoliating.

9. The method for manufacturing a semiconductor device according to claim 8, wherein the etching gas for removing the top layer contains CF₄.

10. The method for manufacturing a semiconductor device according to claim 1, wherein the processed film is a silicon dioxide film.

11. The method for manufacturing a semiconductor device according to claim 1, wherein the bottom layer is a novolac-acrylic resin material.
